(19) United States
(12) Patent Application Publication
(10) Pub. No.: US 2022/0347815 A1
(43) Pub. Date: Nov. 3, 2022

(54) POLISHING PAD AND METHOD FOR MANUFACTURING SAME

(71) Applicant: FUJIBO Holdingus, Inc., Tokyo (JP)

(72) Inventors: Ryuma MATSUOKA, Ehime (JP); Hiroshi KURIHARA, Ehime (JP); Satsuki NARUSHIMA, Ehime (JP); Yamato TAKAMIZAWA, Ehime (JP)

(73) Assignee: FUJIBO Holdingus, Inc., Tokyo (JP)

(21) Appl. No.: 17/764,530

(22) PCT Filed: Sep. 18, 2020
(86) PCT No.: PCT/JP2020/035492

§ 371 Date: Mar. 28, 2022

(30) Foreign Application Priority Data
Sep. 30, 2019 (JP) 2019-180493
Sep. 30, 2019 (JP) 2019-180494

(51) Int. Cl. B24B 37/22; B24B 37/26; B24B 37/013

(52) U.S. Cl. CPC B24B 37/22; B24B 37/26; B24B 37/013

(57) ABSTRACT

A polishing layer having an endpoint detection window is manufactured in the following manner. First, a curing agent and a polymer which form the endpoint detection window are mixed, and then the mixture is poured into a mold to form a columnar material. Next, the roughness of the outer peripheral surface of the columnar material is adjusted, and a plurality of projections and recesses are formed on the outer peripheral surface. Next, in a state where the columnar material is housed in a mold frame, the mixture obtained by mixing the polymer and the curing agent is poured into the mold frame and solidified to create a polyurethane polyurea resin molded article. Next, the polyurethane polyurea resin molded article is horizontally cut with a necessary thickness so as to form a sheet-like member, and the sheet-like member forms a polishing layer having the endpoint detection window.

### TECHNICAL FIELD

The present invention relates to a polishing pad and a method for manufacturing the same, and more particularly to a polishing pad including a transparent endpoint detection window at a predetermined position on a polishing layer and a method for manufacturing the same.

### BACKGROUND ART

In the related art, a polishing pad for polishing a wafer as an article being polished is known, and further, a polishing pad including a transparent endpoint detection window for transmitting inspection light in order to detect an endpoint when polishing the wafer is known (for example, Patent Literature 1 to 3).

Such a polishing pad of the related art has a configuration in which a through-hole is provided on the polishing layer that serves as the main body part, and a transparent window member that serves as an endpoint detection window is attached therein in order to prevent leakage of the polishing liquid (slurry) used for polishing. Specifically, in the polishing pad of Patent Literature 1, a window member that serves as an endpoint detection window is put into a through-hole of a polishing layer and adhered with a photocurable adhesive. In the polishing pad of Patent Literature 2, a window member that serves as an endpoint detection window is fitted into a through-hole of a polishing layer without an adhesive. Furthermore, in the polishing pad of Patent Literature 3, while a single annular recess part is formed on the inner peripheral surface of the through-hole of the polishing layer, an annular projection part engaged with the annular recess part is formed on the outer peripheral surface of the window member that serves as the endpoint detection window.

### REFERENCE LIST

### Patent Literature

Patent Literature 1: Japanese Patent Laid-Open No. 2004-343090

Patent Literature 2: Japanese Patent Laid-Open No. 2004-134539

Patent Literature 3: Japanese Patent Laid-Open No. 2006-110686

### SUMMARY OF INVENTION

### Technical Problem

Incidentally, each of the above-described polishing pads of the related art has the following problems.

In other words, in the polishing pad of Patent Literature 1, since the photocurable adhesive comes into contact with the surface being polished of the wafer while the wafer is being polished, there is a problem that scratches or the like are generated on the surface being polished of the wafer and the polishing performance deteriorates. Further, in the polishing pad of Patent Literature 2, the fitting of the endpoint detection window (window member) into the through-hole of the polishing layer tends to be insufficient, and there is a concern that the endpoint detection window may become detached from the through-hole of the polishing layer during the polishing of the wafer.

Furthermore, in the polishing pad of Patent Literature 3, the polishing surface of the polishing pad and the endpoint detection window are worn away with the use of the polishing pad. Accordingly, when the projection part formed on the outer peripheral surface of the endpoint detection window disappears, there is a concern that the endpoint detection window may easily become detached from the through-hole during subsequent polishing of the wafer.

Therefore, an objective of the present invention is to provide a polishing pad capable of preventing the endpoint detection window from detaching from the polishing layer and a method for manufacturing the same.

### Solution to Problem

In view of the above-described circumstances, according to item 1, the present invention provides a polishing pad including a polishing layer having a polishing surface for polishing an article being polished and an endpoint detection window provided in a through-hole of the polishing layer to transmit inspection light and reflected light from the article being polished, in which a plurality of projection parts is formed on a side part of the endpoint detection window in a direction orthogonal to the polishing surface, a plurality of recess parts engaged with the projection parts of the endpoint detection window is formed on an inner peripheral surface of the through-hole of the polishing layer, and the projection parts and the recess parts at a plurality of locations are engaged with each other.

According to item 7, the present invention provides a method for manufacturing a polishing pad including a polishing layer having a polishing surface for polishing an article being polished and an endpoint detection window provided on the polishing layer to transmit inspection light and reflected light from the article being polished, the method including: a first mixing step of mixing a curing agent and a prepolymer which form the endpoint detection window and forming a mixture of the prepolymer and the curing agent; a first molding step of producing a material that forms the endpoint detection window by pouring the mixture into a first mold and solidifying the mixture; a projections and recesses forming step of forming a plurality of projections and recesses on a side surface of the material; a second mixing step of forming a mixture obtained by mixing the curing agent and the polymer which form the polishing layer; a second molding step of housing the material, in which the plurality of projections and recesses is formed on the side surface, on an inside of a second mold, and then pouring the mixture formed in the second mixing step into the second mold and solidifying the mixture to produce a molded article in a state where the material is embedded; and a cutting step of removing the molded article from the second mold and then cutting the molded article to a required thickness to form the polishing layer having the endpoint detection window.

### Advantageous Effects of Invention

According to the configuration of item 1, the endpoint detection window is attached to the through-hole in a state where the projections and recesses at a plurality of locations are engaged with each other without using an adhesive. Therefore, during the polishing of the article being polished, the surface being processed is not adversely affected by the adhesive, and the plurality of recess parts and the projection parts is engaged with each other. Thus, it is possible to prevent the endpoint detection window from detaching from the through-hole of the polishing layer during the polishing of the article being polished.

Further, according to the configuration of item 7, the endpoint detection window is attached to the polishing layer in a state where the projections and recesses at the plurality of locations are engaged with each other. Therefore, the surface area becomes large due to the projections and recesses formed on the side surface of the endpoint detection window, the bonding strength of the endpoint detection window with respect to the polishing layer increases, and it is possible to prevent the endpoint detection window from detaching from the through-hole of the polishing layer during the polishing of the article being polished.

### BRIEF DESCRIPTION OF DRAWINGS

FIG. 1 is a schematic perspective view illustrating an example of the present invention.

FIG. 2 is a sectional view of a main part along the line II-II of FIG. 1. FIG. 3 is an enlarged view of the main part of FIG. 2.

FIG. 4 is a view illustrating a manufacturing process of a polishing layer of a polishing pad illustrated in FIG. 3.

FIG. 5 is a view illustrating a manufacturing process of the polishing layer of the polishing pad of another example according to the present invention.

FIG. 6 is a sectional view of a main part of FIG. 5, (a) of FIG. 6 illustrates a state before use of the polishing pad, and (b) of FIG. 6 illustrates a state after use.

FIG. 7 is a sectional view illustrating another example of the present invention, (a) of FIG. 7 illustrates a state before use of the polishing pad, and (b) of FIG. 7 illustrates a state after use.

FIG. 8 is a sectional view illustrating another example of the present invention, (a) of FIG. 8 illustrates a state before use of the polishing pad, and (b) of FIG. 8 illustrates a state after use.

### DESCRIPTION OF EMBODIMENTS

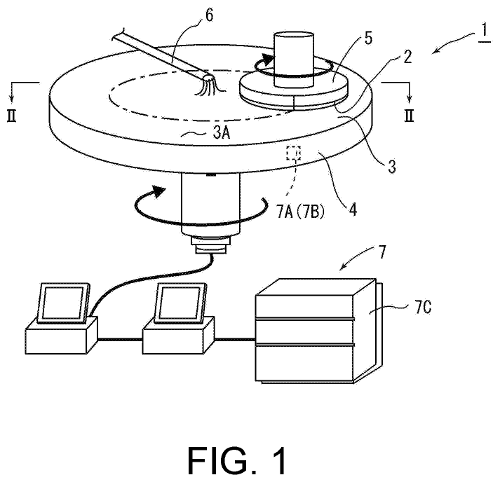

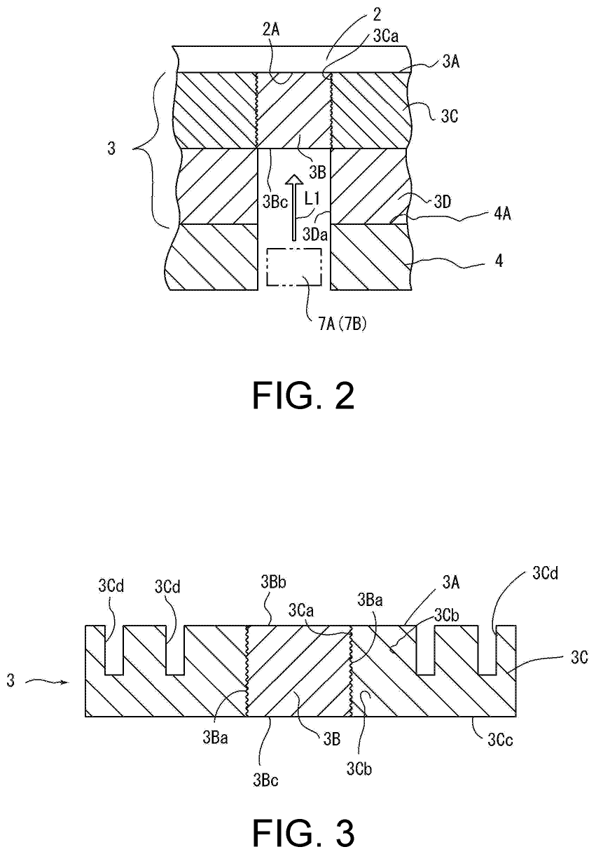

Hereinafter, the present invention will be described with respect to the illustrated examples. In FIGS. 1 and 2, 1 indicates a polishing device, and the polishing device 1 polishes a thin plate-shaped article being polished 2 (for example, a semiconductor wafer) with a polishing pad 3. This polishing device 1 irradiates a surface being polished 2A of the article being polished 2 with inspection light L1 when performing the polishing process to polish the article being polished 2, and accordingly, the progress of the polishing process and the endpoint at which the process is completed can be detected.

The polishing device 1 includes a polishing surface plate 4 positioned on the lower side and having the polishing pad 3 fixed to the upper surface; a holding surface plate 5 positioned on the upper side and holding the article being polished 2 on the lower surface; a slurry supply mechanism 6 for supplying a slurry between the article being polished 2 and the polishing pad 3; and a detection mechanism 7 for detecting the progress of polishing process of the article being polished 2 and the endpoint of the process using the inspection light L1.

The article being polished 2, which is a target of the polishing process by the polishing device 1 is an optical material, a silicon wafer, a liquid crystal glass substrate, a semiconductor substrate, as well as a plate-like object of such as glass, metal, or ceramic.

Further, as the slurry supplied by the slurry supply mechanism 6, a known suitable slurry of the related art can be used depending on the article being polished 2 which is a target and the required processing accuracy.

The polishing surface plate 4 and the holding surface plate 5 each have a substantially disk shape, each of these is rotated in the direction of an arrow by a driving mechanism (not illustrated), and the holding surface plate 5 is provided so as to be able to move up and down.

When polishing the article being polished 2, in a state where the holding surface plate 5 presses the surface being polished (lower surface) 2A of the article being polished 2 against a polishing surface 3A of the polishing pad 3 at a set pressure, these are relatively rotated, and the slurry is supplied from the slurry supply mechanism 6 between the surface being polished 2A of the article being polished 2 and the polishing surface 3A of the polishing pad 3.

Incidentally, when polishing the article being polished 2, it is necessary to detect the progress of the polishing process of the article being polished 2 and the endpoint at which the process ends. Therefore, this polishing device 1 includes the detection mechanism 7 that emits the inspection light L1 from the lower side to the upper side and detects the progress and the process endpoint of the polishing process based on the reflected light from the surface being polished 2A of the article being polished 2. Further, at a predetermined position on the polishing pad 3, a transparent endpoint detection window 3B that transmits the inspection light L1 and transmits the reflected light from the surface being polished 2A of the article being polished 2 is provided.

The polishing pad 3 includes a disk-shaped polishing layer 3C positioned on the upper side and a disk-shaped support layer 3D adhered to the lower surface of the polishing layer 3C with an adhesive. The transparent endpoint detection window 3B is provided at a predetermined position on the polishing layer 3C, and at the position of the support layer 3D below the transparent endpoint detection window 3B, a through-hole 3Da for allowing the inspection light L1 and the reflected light from the article being polished 2 to pass therethrough is formed.

An upper surface 3Bb of the endpoint detection window 3B and the polishing surface 3A which is the upper surface of the polishing layer 3C are flush with each other. Further, a lower surface 3Bc of the endpoint detection window 3B and the lower surface of the polishing layer 3C are flush with each other, and the upper surface of the support layer 3D is adhered thereto with an adhesive. The lower surfaces (lower surface of the support layer 3D) of the polishing pad 3 formed of the polishing layer 3C and the support layer 3D, which are vertically integrated, are fixed to an upper surface 4A of the polishing surface plate 4 with an adhesive.

The polishing layer 3C is formed of rigid urethane. The rigid urethane is manufactured by a prepolymer method of curing a polyurethane polyurea resin obtained by adding together and mixing a curing agent (chain extender) such as diamines or diols, a foaming agent, a catalyst, and the like using a urethane prepolymer which is a reaction intermediate between a polyol component and an isocyanate component. Although the polishing layer or the endpoint detection window will be described below as the polyurethane polyurea resin, a polyurethane resin or a polyurea resin may be used.

A method for manufacturing the polishing layer 3C includes, for example, a preparing step of preparing at least a polyurethane bond-containing isocyanate compound as a prepolymer, a curing agent, and a hollow body; a mixing step of mixing at least the polyurethane bond-containing isocyanate compound and a curing agent to obtain a mixed solution for molding a molded article; a molded article molding step of molding a polyurethane polyurea resin molded article from the mixed solution for molding a molded article; and a polishing layer forming step of forming a polishing layer having the polishing surface from the polyurethane polyurea resin molded article.

In the preparing step, for the manufacturing of the polishing layer 3C, for example, a polyurethane bond-containing isocyanate compound, a curing agent, and a hollow body are used as raw materials for the polyurethane polyurea resin molded article.

Furthermore, a polyol compound may be used together with the above components, and components other than the above may be used in combination as long as the effects of the present invention are not impaired.

The polyurethane bond-containing isocyanate compound prepared in the preparing step is a compound obtained by reacting the following polyisocyanate compound with a polyol compound under normally used conditions, and contains a polyurethane bond and an isocyanate group in the molecule. Further, other components may be contained in the polyurethane bond-containing isocyanate compound as long as the effects of the present invention are not impaired. As the polyurethane bond-containing isocyanate compound, a commercially available compound may be used, or a compound synthesized by reacting a polyisocyanate compound with a polyol compound may be used. The above reaction is not particularly limited, and the addition polymerization reaction may be carried out using known methods and conditions in the manufacturing of a polyurethane resin. For example, the manufacturing is possible by a method in which a polyisocyanate compound heated to 50° C. while stirring in a nitrogen atmosphere is added to a polyol compound heated to 40° C., and after 30 minutes, the temperature is further raised to 80° C. and reaction is performed at 80° C. for 60 minutes.

First, the polyisocyanate compound means a compound having two or more isocyanate groups in the molecule. The polyisocyanate compound is not particularly limited as long as the polyisocyanate compound has two or more isocyanate groups in the molecule.

Examples of a diisocyanate compound having two isocyanate groups in a molecule include m-phenylene diisocyanate, p-phenylene diisocyanate, 2,6-tolylene diisocyanate (2,6-TDI), 2,4-tolylene diisocyanate (2,4-TDI), naphthalene-1,4-diisocyanate, diphenylmethane-4,4′-diisocyanate (MDI), 4,4′-methylene-bis(cyclohexyl isocyanate) (hydrogenated MDI), 3,3′-dimethoxy-4,4′-biphenyl diisocyanate, 3,3′-dimethyldiphenylmethane-4,4′-diisocyanate, xylylene-1,4-diisocyanate, 4,4′-diphenylpropane diisocyanate, trimethylene diisocyanate, hexamethylene diisocyanate, propylene-1,2-diisocyanate, butylene-1,2-diisocyanate, cyclohexylene-1,2-diisocyanate, cyclohexylene-1,4-diisocyanate, p-phenylene diisothiocyanate, xylylene-1,4-diisothiocyanate, and ethylidyne diisothiocyanate.

Furthermore, as the polyisocyanate compound, a diisocyanate compound is preferable, and among these, 2,4-TDI, 2,6-TDI, and MDI are more preferable, and 2,4-TDI and 2,6-TDI are particularly preferable.

These polyisocyanate compounds may be used alone or in combination of a plurality of polyisocyanate compounds.

Next, the above polyol compound means a compound having two or more alcoholic hydroxyl groups (OH) in the molecule.

Examples of a polyol compound used for synthesizing the polyurethane bond-containing isocyanate compound include diol compounds such as ethylene glycol, diethylene glycol (DEG), and butylene glycol, triol compounds and the like; polyether polyol compounds such as poly(oxytetramethylene)glycol (or polytetramethylene ether glycol) (PTMG); polyester polyol compounds such as a reactant of ethylene glycol and adipic acid and a reactant of butylene glycol and adipic acid; and polycarbonate polyol compound, polycaprolactone polyol compound and the like.

Further, trifunctional propylene glycol to which ethylene oxide is added can also be used. Among these, PTMG or a combination of PTMG and DEG is preferable. The above polyol compound may be used alone or in combination of a plurality of polyol compounds.

Here, the NCO equivalent of the prepolymer, which indicates the molecular weight of the prepolymer per one NCO group, is preferably 200 to 800, more preferably 300 to 700, and further preferably 400 to 600.

Specifically, the NCO equivalent of the above prepolymer can be obtained as follows.

NCO equivalent of prepolymer=(parts by mass of polyisocyanate compound+parts by mass of polyol compound)/[(number of functional groups per one molecule of polyisocyanate compound x parts by mass of polyisocyanate compound/molecular weight of polyisocyanate compound)−(number of functional groups per one molecule of polyol compound x parts by mass of polyol compound/molecular weight of polyol compound)]

As the curing agent, for example, a polyamine compound and/or a polyol compound can be used.

The polyamine compound means a compound having two or more amino groups in the molecule, and an aliphatic or aromatic polyamine compound, particularly a diamine compound can be used.

Examples thereof include ethylenediamine, propylenediamine, hexamethylenediamine, isophoronediamine, dicyclohexylmethane-4,4′-diamine, 3,3′-dichloro-4,4′-diaminodiphenylmethane (methylene-bis-o-chloroaniline) (hereinafter, abbreviated as MOCA), and polyamine compounds having the same structure as that of MOCA.

Further, the polyamine compound may have a hydroxyl group, and examples of such an amine compound include 2-hydroxyethylethylenediamine, 2-hydroxyethylpropylenediamine, di-2-hydroxyethylethylenediamine, di-2-hydroxyethylpropylenediamine, 2-hydroxypropylethylenediamine, and di-2-hydroxypropylethylenediamine.

As the polyamine compound, a diamine compound is preferable, MOCA, diaminodiphenylmethane, and diaminodiphenylsulfone are more preferable, and MOCA is particularly preferable.

The polyamine compound may be used alone or in combination of a plurality of polyamine compounds.

The polyamine compound is preferably defoamed under reduced pressure in a heated state, if necessary, in order to facilitate mixing with other components and/or to improve the uniformity of the bubble diameter in the subsequent molded article forming step. As a defoaming method under reduced pressure, a known method in manufacturing of polyurethane may be used, and for example, defoaming can be performed at a vacuum degree of 0.1 MPa or less using a vacuum pump.

When a solid compound is used as a curing agent, defoaming under reduced pressure is possible while being melted by heating.

Further, as the polyol compound as a curing agent, any compound such as a diol compound or a triol compound can be used without particular limitation. The polyol compound as a curing agent may also be the same as or different from the polyol compound used to form the prepolymer. Specific examples thereof include low molecular weight diols such as ethylene glycol, diethylene glycol, triethylene glycol, 1,2-propanediol, 1,3-propanediol, 1,3-butanediol, 1,4-butanediol, neopentyl glycol, pentanediol, 3-methyl-1,5-pentanediol, and 1,6-hexanediol; and high molecular weight polyol compounds such as poly(oxytetramethylene)glycol, polyethylene glycol, and polypropylene glycol. The above polyol compound may be used alone or in combination of a plurality of polyol compounds.

Here, each component is mixed such that the R value, which is the equivalent ratio of the active hydrogen groups (amino groups and hydroxyl groups) present in the curing agent to the isocyanate groups present at the ends of the polyurethane bond-containing isocyanate compound, is 0.60 to 1.40. The R value is preferably 0.65 to 1.30, more preferably 0.70 to 1.20.

The hollow body means a microsphere having a void. Microspheres include spherical, elliptical, and similar shapes. Examples of a hollow body include an unfoamed heat-expandable microsphere composed of an outer shell (polymer shell) made of a thermoplastic resin and a low boiling point hydrocarbon contained in the outer shell, and those obtained by heating and expanding the unfoamed heat-expandable microsphere.

Examples of a polymer shell include a thermoplastic resin such as acrylonitrile-vinylidene chloride copolymer, acrylonitrile-methylmethacrylate copolymer, and vinyl chloride-ethylene copolymer, as disclosed in Japanese Patent Laid-Open No. 57-137323. Similarly, examples of a low boiling point hydrocarbon contained in the polymer shell include isobutane, pentane, isopentane, and petroleum ether.

In addition to using the above hollow body, bubbles may be formed by using chemical foaming such as water foaming or foaming by mechanical stirring, or these methods may be combined.

Next, the mixing step will be described. In the mixing step, the polyurethane bond-containing isocyanate compound as a prepolymer, the curing agent, and the hollow body, which are prepared in the above preparing step, are supplied into the mixer and stirred and mixed. The mixing step is performed in a state of being heated to a temperature at which the flowability of each of the above components can be ensured.

The mixing order is not particularly limited, but it is preferable that a mixed solution obtained by mixing a polyurethane bond-containing isocyanate compound and a hollow body with each other and a mixed solution obtained by mixing a curing agent and other components with each other if necessary be prepared, and both mixed solutions be supplied into the mixer and mixed and stirred. In this manner, a mixed solution for molding a molded article is prepared.

Next, in the molded article molding step, the mixed solution for molding a molded article prepared in the above mixing step is poured into a mold frame at 50 to 100° C., and a polyurethane polyurea resin is formed by reacting the prepolymer and the curing agent. Accordingly, the mixed solution is cured to form a polyurethane polyurea presin molded article.

Then, in the polishing layer forming step, the polyurethane polyurea resin molded article obtained by the molded article molding step is sliced into a sheet shape, and the sliced resin sheet is cut into a predetermined shape. The front surface and/or the back surface of the resin sheet shape obtained in this manner is ground. One surface becomes the polishing surface, and by performing cutting or the like on the polishing surface using a required cutter, grooves having any pitch, width, and depth can be formed, and accordingly, the polishing layer 3C will be obtained.

As the support layer 3D, an impregnated non-woven fabric impregnated with a resin, a foam such as polyethylene foam or polyurethane foam, or a support base material such as polyethylene terephthalate (PET) can be used.

When the impregnated non-woven fabric is used as the support layer 3D, the manufacturing of the support layer 3D includes at least a step of wet-coagulating the resin impregnated in the non-woven fabric base and a step of buffing both surfaces of the wet-coagulated fiber aggregate. The non-woven fabric base of the present example is not particularly limited, and various known non-woven fabric bases can be adopted.

Examples of a non-woven fabric base include non-woven fabrics such as polyolefine-based, polyamide-based, and polyester-based non-woven fabrics. Further, the method of entangling the fibers when obtaining the non-woven fabric base is not particularly limited, and may be, for example, needle punching or hydroentanglement.

As the non-woven fabric base, one of the above-described types can be used alone, and two or more types can be used in combination. The non-woven fabric base has many gaps between fibers and is rich in water absorption, but the gaps are filled with the resin by impregnating the resin, and thus the water absorption is lowered.

Examples of a resin to be impregnated in a non-woven fabric base include a polyurethane type such as polyurethane and polyurethane polyurea; an acrylic type such as polyacrylate and polyacrylonitrile; a vinyl type such as polyvinylchloride, polyvinyl acetate, and polyvinylidene fluoride; a polysulfone type such as polysulfone and polyethersulfone; an acylated cellulose type such as acetylated cellulose and butyrylated cellulose; a polyamide type; and a polystyrene type.

The density of the non-woven fabric is preferably 0.3 g/cm³ or less, more preferably 0.1 to 0.2 g/cm³ in a state before resin impregnation (web state). The density of the non-woven fabric after resin impregnation is preferably 0.5 g/cm³ or less, more preferably 0.3 to 0.4 g/cm³. When the density of the non-woven fabric is extremely high, the processing accuracy tends to deteriorate, and when the density is extremely low, water absorption tends to be relatively easy.

The adhesion ratio of the resin to the non-woven fabric is expressed by the weight of the adhered resin with respect to the weight of the non-woven fabric, and is preferably 50% or more, more preferably 75 to 200%. When the adhesion rate of the resin is extremely large, the non-woven fabric tends not to show desired cushioning properties as the support layer 3D, and when the adhesion ratio is extremely low, the support layer 3D absorbs water, which affects the polishing characteristics.

A case where a polyurethane resin is used as an example of impregnating a non-woven fabric base with a resin and performing wet coagulation will be described.

The polyurethane resin, a solvent, which can dissolve the polyurethane resin and is miscible with the coagulation solution which will be described later, and other additives if necessary are mixed with each other, and if necessary, the mixture is further defoamed under reduced pressure to prepare a polyurethane resin solution. The solvent is not particularly limited, and examples thereof include N,N-dimethylformamide (DMF), isopropyl alcohol (IPA), and N,N-dimethylacetamide. For example, the polyurethane resin may be dissolved in a solvent in the range of 5 to 25% by mass, more preferably in the range of 8 to 15% by mass, based on the total amount of the polyurethane resin solution. In a case of the above range, the polyurethane resin can easily spread throughout the entire non-woven fabric base.

Next, after immersing the sheet-shaped non-woven fabric in the polyurethane resin solution, the resin solution is squeezed out using a mangle roller capable of pressurizing between the pair of rollers to adjust the adhesion amount of the resin solution to the desired adhesion amount, and to substantially uniformly impregnate the non-woven fabric base with the resin solution. Next, the polyurethane resin is coagulated and regenerated by immersing the non-woven fabric base impregnated with the resin solution in a coagulation solution containing a poor solvent for the resin, for example, water, as a main component. An organic solvent such as a polar solvent other than the solvent in the resin solution may be added to the coagulation solution in order to adjust the regeneration speed of the resin. The temperature of the coagulation solution is not particularly limited as long as the coagulation of the resin is possible at this temperature, and may be, for example, 15 to 60° C. Then, if necessary, the solvent remaining in the non-woven fabric impregnated with the resin may be removed by using a cleaning solution known from the related art, and further, the cleaning solution may be removed by using a mangle roller or drying. In this manner, a fiber aggregate in which the resin is wet-coagulated can be obtained. After this, both surfaces of the fiber aggregate are buffed to adjust the thickness of the fiber aggregate.

In the fiber aggregate of which the thickness has been adjusted, through-holes are formed at predetermined positions in the thickness direction. The through-holes can be formed by drilling or the like. Accordingly, the support layer 3D can be obtained.

For the support layer 3D, for example, a transparent base material of polyethylene terephthalate (PET) can also be used. By using a double-sided tape or an adhesive on both surfaces of the base material of polyethylene terephthalate, if necessary, by pressurizing, adhesion and fixing to the polishing layer 3C are possible. The double-sided tape or the adhesive used for adhesion to the polishing layer 3C is not particularly limited, and can be selected and used in any manner from the double-sided tapes and adhesives known in the technical field. When the base material is transparent, the inspection light is transmitted, and thus a through-hole may not be provided.

The endpoint detection window 3B can use the same material as that of the polishing layer 3C, and is formed of, for example, rigid urethane. The rigid urethane of the endpoint detection window 3B is manufactured by a prepolymer method of curing a polyurethane polyurea resin obtained by adding and mixing a curing agent (chain extender) such as diamines or diols, an additive, a catalyst, and the like using a urethane prepolymer.

As the urethane prepolymer used for the endpoint detection window 3B, for example, a polyurethane bond-containing isocyanate compound similar to the polishing layer can be used. As the polyurethane bond-containing isocyanate compound, a commercially available compound may be used, or a compound synthesized by reacting a polyisocyanate compound with a polyol compound may be used. The above reaction is not particularly limited, and the addition polymerization reaction may be carried out using known methods and conditions in the manufacturing of a polyurethane resin. Further, other components may be contained in the polyurethane bond-containing isocyanate compound as long as the effects of the present invention are not impaired.

As the polyisocyanate compound, a diisocyanate compound is preferable, and a diisocyanate compound used in the polishing layer can be used. Among the diisocyanate compounds, 2,4-TDI, 2,6-TDI, and MDI are more preferable, and 2,4-TDI and 2,6-TDI are particularly preferable. These polyisocyanate compounds may be used alone or in combination of a plurality of polyisocyanate compounds.

As the polyol compound used for synthesizing the polyurethane bond-containing isocyanate compound, the polyol compound used in the polishing layer can also be used.

Among the polyol compounds, PTMG or a combination of PTMG and DEG is preferable. The above polyol compound may be used alone or in combination of a plurality of polyol compounds.

Regarding the prepolymer used for the endpoint detection window 3B, the NCO equivalent of the prepolymer, which indicates the molecular weight of the prepolymer per one NCO group, is preferably 200 to 800, more preferably 300 to 700, and further preferably 400 to 600.

As the curing agent, for example, a polyamine compound and/or a polyol compound can be used similar to the compound used in the polishing layer 3C. As the polyamine compound, a diamine compound is preferable, MOCA, diaminodiphenylmethane, and diaminodiphenylsulfone are more preferable, and MOCA is particularly preferable. The polyamine compound may be used alone or in combination of a plurality of polyamine compounds.

The polyamine compound used for the endpoint detection window 3B is preferably defoamed under reduced pressure in a heated state if necessary to facilitate mixing with other components and/or to remove air bubbles, as in a case of the polishing layer.

Further, as the polyol compound as a curing agent used for the endpoint detection window 3B, any compound such as a diol compound or a triol compound can be used without particular limitation. The polyol compound as a curing agent may also be the same as or different from the polyol compound used to form the prepolymer used for the endpoint detection window 3B. The above polyol compound may be used alone or in combination of a plurality of polyol compounds.

Here, each component is mixed such that the R value, which is the equivalent ratio of the active hydrogen groups (amino groups and hydroxyl groups) present in the curing agent used for the endpoint detection window to the isocyanate groups present at the ends of the polyurethane bond-containing isocyanate compound used for the endpoint detection window 3B, is 0.60 to 1.40. The R value is preferably 0.65 to 1.30, more preferably 0.70 to 1.20.

Known antioxidants, ultraviolet absorbers, and light stabilizers can be used as additives for the endpoint detection window 3B. By using these additives, it is possible to suppress yellowing or deterioration of the endpoint detection window.

The polishing surface plate 4 includes a light emitting part 7A that emits the inspection light L1 vertically upward, and a light receiving part 7B for receiving the reflected light from the article being polished 2, at a position below the endpoint detection window 3B and the through-hole 3Da of the support layer 3D of the polishing pad 3. The detection mechanism 7 includes the light emitting part 7A, the light receiving part 7B, and a control part 7C that controls their operations and detects the progress of the process during polishing and the endpoint at which the process ends. During polishing of the article being polished 2, the inspection light L1 is radiated upward from the light emitting part 7A of the detection mechanism 7, and thus the inspection light L1 transmits through the transparent endpoint detection window 3B and irradiates the surface being polished 2A of the article being polished 2. Then, the inspection light L1 is reflected downward by the surface being polished 2A of the article being polished 2, and the reflected light transmits through the transparent endpoint detection window 3 and is detected by the light receiving part 7B. The reflected light detected by the light receiving part 7B is transmitted to the control part 7C.

Then, as the polishing process of the article being polished 2 progresses and the surface being polished 2A of the article being polished 2 is gradually polished, the intensity or the like of the reflected light detected by the light receiving part 7B changes.

When the intensity or the like of the reflected light detected by the light receiving part 7B becomes the intensity or the like registered in advance, the control part 7C determines that the surface being polished 2A has reached the endpoint of the process, and stops the polishing process. Then, since the driving mechanism is stopped, the rotation of the polishing surface plate 4 and the holding surface plate 5 is stopped, and the supply of the slurry from the slurry supply mechanism 6 is also stopped.

The detection mechanism 7 detects the endpoint of the polishing process when the article being polished 2 is polished in this manner. The configuration of the detection mechanism 7 using the inspection light L1 is known from Patent Literature 1 to 3 described above.

Therefore, in the present example, the endpoint detection window 3B provided in the polishing layer 3C, the attachment location thereof and the like are improved as follows, and accordingly, the endpoint detection window 3B is prevented from being detached from the polishing layer 3C during the process.

As illustrated in FIG. 3, a through-hole 3Ca in the up-down direction is formed at a predetermined position on the polishing layer 3C, and a substantially columnar endpoint detection window 3B is provided in a state of being engaged without a gap.

The endpoint detection window 3B is formed in a short columnar shape having substantially the same axial dimension and outer diameter. An outer peripheral surface 3Ba, which is the side surface of the endpoint detection window 3B, is formed with minute projections and recesses by adjusting the surface roughness. The endpoint detection window 3B is formed by curing a mixture of urethane prepolymer and a curing agent, and the light can be transmitted therethrough. Although it has been described that the endpoint detection window 3B is columnar, the endpoint detection window 3B may be a prism such as a square prism.

The surface roughness Ra (arithmetic average roughness) of the outer peripheral surface 3Ba of the endpoint detection window 3 is preferably 2 to 50 μm, more preferably 2 to 40 μm, and even more preferably 2 to 30 μm. When the surface roughness of the outer peripheral surface 3Ba is within the range, it is possible to suppress the influence on the article being polished (scratch generation or the like) while ensuring the surface area of the outer peripheral surface 3Ba necessary for increasing the bonding strength. The surface roughness can be measured based on the Japanese Industrial Standards (JIS B 0601-1994). Specifically, the surface roughness can be obtained by averaging arithmetic average roughnesses Ra obtained by measuring 5 different locations on the side surface of the columnar material which will be described later. When the columnar material has a columnar shape, the surface roughness can be obtained by measuring the side surface of the columnar material along the thickness direction. As the measuring device, for example, a surface roughness measuring machine (SURFCOM SR-2 manufactured by TOKYO SEIMITSU CO., LTD.) can be used. The measurement speed was 0.6 mm/sec, the measurement distance was 12.5 mm, and the cutoff value was 2.5 mm.

In other words, the original outer peripheral surface 3Ba of the endpoint detection window 3B is fitted to the original inner peripheral surface of the through-hole 3Ca without a gap. Further, the inner peripheral surface of the through-hole 3Ca has a shape that matches the surface shape of the outer peripheral surface 3Ba of the endpoint detection window 3B.

In other words, a plurality of minute projections and recesses is formed on the outer peripheral surface 3Ba of the endpoint detection window 3B by adjusting the surface roughness, while a plurality of projections and recesses that is engaged with the plurality of minute projections and recesses on the outer peripheral surface 3Ba of the endpoint detection window 3B is formed on the inner peripheral surface of the through-hole 3Ca of the polishing layer 3C without a gap.

The upper surface 3Bb of the endpoint detection window 3B is flush with the polishing surface 3A of the polishing layer 3C, and the lower surface 3Bc of the endpoint detection window 3 is flush with a lower surface 3Cc of the polishing layer 3C.

The upper surface of the polishing layer 3C is a polishing surface 3A that slides on the surface being polished 2A of the article being polished 2, and grooves 3Cd are formed at predetermined positions of the polishing surface 3A. The grooves 3Cd are formed on the polishing surface 3A in a grid pattern, a concentric pattern, a radial pattern, or the like. The depths of the grooves 3Cd are all the same. Further, the groove 3Cd holds or discharges the slurry. The polishing layer 3C and the endpoint detection window 3B in the polishing pad 3 of the present example are configured as described above.

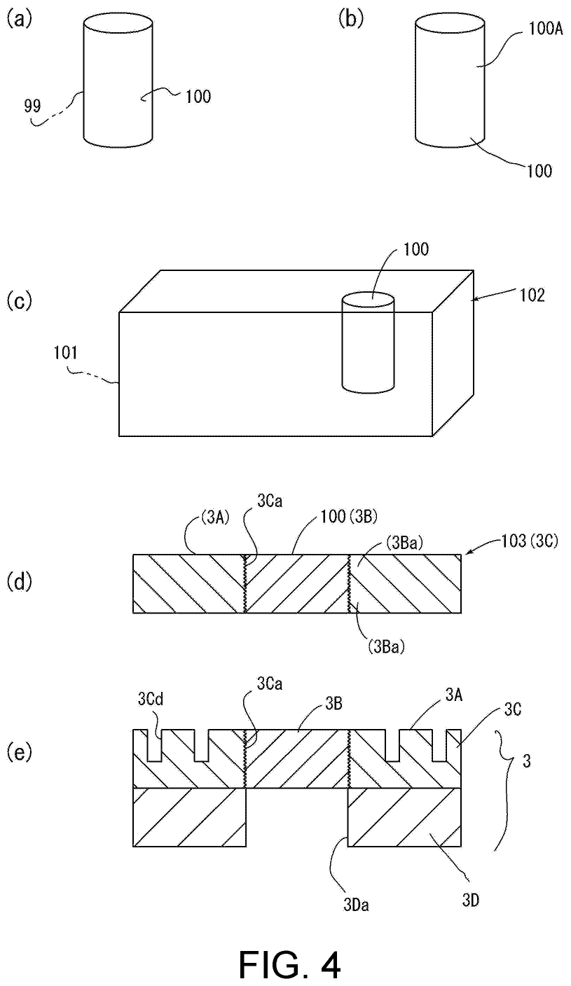

Next, one aspect of the method for manufacturing the polishing layer 3C of the polishing pad 3 configured as described above will be described with reference to FIG. 4.

In other words, first, the columnar material 100 having a required outer diameter and axial length is formed. In the aspect of the present example, the columnar material having a columnar shape is described, but a columnar material having a prism shape such as a square prism shape may be used. The columnar material 100 becomes a window member that later becomes the endpoint detection window 3B. In the aspect of the present example, a urethane prepolymer and a curing agent are prepared as materials for the columnar material, a mixture obtained by mixing these is formed (first mixing step), and the mixture is poured into a cylindrical mold 99 (not illustrated) and cured to form the columnar material 100 (first molding step, refer to (a) of FIG. 4). Next, projections and recesses are formed on an outer peripheral surface 100A of the columnar material 100 by adjusting the roughness of the surface (projections and recesses forming step). In the aspect of the present example, innumerable minute projections and recesses are formed with sandpaper (#120) over the entire outer peripheral surface 100A of the columnar material 100 (refer to (b) of FIG. 4). The surface roughness Ra of the outer peripheral surface before the projections and recesses forming step was 1.6 μm, and the surface roughness after the projections and recesses forming was 4.7 μm.

Next, a rectangular box-shaped mold frame 101 (not illustrated) is prepared, and is installed at a predetermined position within the mold frame 101 such that the columnar material 100 in which the innumerable minute projections and recesses are formed on the outer peripheral surface 100A is oriented in the vertical direction.

Then, the urethane prepolymer used as the material of the polishing layer 3C and the curing agent are mixed to form a mixture (second mixing step), and the mixture is poured into the mold frame 101 and solidified (second molding step). Accordingly, the polyurethane polyurea resin molded article 102 having the same shape as that of the internal space of the mold frame 101 is formed in a state where the columnar material 100 is integrally embedded (refer to (c) of FIG. 4). The polyurethane polyurea resin molded article 102 serves as a part of the above-described polishing layer 3C.

Since the mixed solution obtained by mixing the urethane prepolymer used as the material of the polishing layer 3C and the curing agent with each other is in a liquid state, when the mixed solution is poured into the mold frame 101, the mold frame is filled with the mixed solution up to the outer peripheral surface 100A of the columnar material 100 without any gap and the mixed solution is solidified.

Next, after the polyurethane polyurea resin molded article 102 is removed from the mold frame 101, the location where the columnar material 100 is embedded in the polyurethane polyurea resin molded article 102 is thinly cut along a horizontal plane so as to have a required thickness, and is cut out as a plurality of sheet-like members 103 (cutting step, refer to (d) of FIG. 4).

Then, the upper surface and the lower surface of the sheet-like member 103 are polished so as to be smooth. After this, the double-sided tape or the like is adhered to the lower surface of the polishing layer 3C on the surface opposite to the polishing surface 3A. Further, the grooves (3Cd) for discharging or holding the slurry is formed at a required position on the upper surface of the polishing surface 3A. Accordingly, the polishing layer 3C of the polishing pad 3 of the present example illustrated in FIG. 3 is completed (refer to (d) of FIG. 4).

In this manner, the polishing layer 3C of the polishing pad 3 is formed, and the location of the columnar material 100 in the polishing layer 3C becomes the endpoint detection window 3B. The outer peripheral surface 3Ba of the endpoint detection window 3B has a surface roughness adjusted to form innumerable minute projections and recesses, and these projections and recesses are in a state of being engaged with the through-hole 3Ca on the polishing layer 3C side at an adjacent position without a gap.

In other words, in a state where the surface area of the outer peripheral surface 3Ba increased due to the innumerable minute projections and recesses formed on the outer peripheral surface 3Ba of the endpoint detection window 3B, a state of being engaged with the projections and recesses of the inner peripheral surface of the through-hole 3Ca of the polishing layer 3C without a gap is achieved.

After the polishing layer 3C is formed in this manner, the support layer 3D having the through-hole 3Da formed in advance is adhered to the lower surface of the polishing layer 3C with an adhesive. Accordingly, the manufacturing of the polishing pad 3 of the present example is completed ((e) of FIG. 4).

The lower surface (lower surface of the support layer 3D) of the polishing pad 3 manufactured in this manner is fixed to the upper surface of the polishing surface plate 4 with a double-sided tape or an adhesive.

A comparison was performed in a case where a polishing layer was prepared using each of the columnar material subjected to the projections and recesses forming step and the columnar material not subjected to the projections and recesses forming step. The polishing layer formed of a columnar material which is not subjected to the projections and recesses forming step has a small surface area on the outer peripheral surface of the endpoint detection window and a small bonding strength to the through-hole of the polishing layer, and thus the endpoint detection window comes off from the polishing layer when the endpoint detection window is pressed. Meanwhile, in the polishing layer formed of the columnar material subjected to the projections and recesses forming step, the surface area of the outer peripheral surface of the endpoint detection window increases and the bonding strength to the through-hole of the polishing layer increases, and thus the endpoint detection window does not come off from the polishing layer even when the endpoint detection window is pressed.

As the projections and recesses forming step, an example of adjusting the roughness of the side surface of the columnar material by shot blasting or sandpaper has been described, but the present invention is not limited thereto. As another example, a polyurethane polyurea resin molded article is formed without embedding a columnar material, a through-hole is formed at a predetermined position of the polyurethane polyurea resin molded article, and the projections and recesses forming step is performed with respect to the inner peripheral surface of the through-hole by shot blasting or sandpaper. After this, by pouring the mixed solution obtained by mixing the endpoint detection window urethane prepolymer and the curing agent with each other into the through-holes of which the surface roughness has been adjusted and curing the mixed solution, the innumerable fine projections and recesses can be formed on the columnar material.

In the present example, the polishing layer 3C of the polishing pad 3 is produced as described above, and the support layer 3D is adhered to the polishing layer 3C with a double-sided tape or an adhesive to produce the polishing pad 3.

The polishing layer 3C of the polishing pad 3 of the present example is attached in a state where the endpoint detection window 3B is engaged with the through-hole 3Ca of the polishing layer 3C without a gap without using an adhesive. Therefore, during the polishing process in which the polishing surface 3A of the polishing layer 3C slides on the surface being polished 2A of the article being polished 2, the adhesive does not mix into the polishing surface 3A, and adverse effect (scratches and the like) of the article being polished 3A due to the adhesive can be prevented.

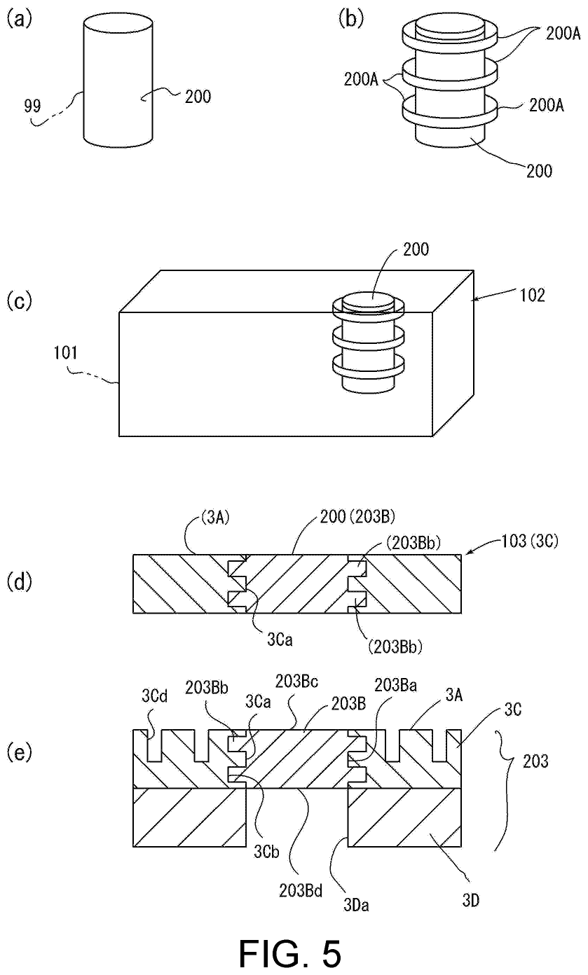

Further, in the projections and recesses forming step illustrated in (b) of FIG. 4, innumerable minute projections and recesses are formed by shot blasting or sandpaper over the entire side surface (outer peripheral surface 100A) of the columnar material 100, but as illustrated in FIG. 5, a plurality of bulging parts 200A can be formed on the columnar material 200 by cutting.

As illustrated in (e) of FIG. 5, a through-hole 3Ca in the up-down direction is formed at a predetermined position on the polishing layer 3C, and a substantially columnar endpoint detection window 203B is provided in a state of being engaged without a gap.

The endpoint detection window 203B is formed in a short columnar shape having substantially the same axial dimension and outer diameter. Flange-shaped bulging parts 203Bb are formed at two locations on the outer peripheral surface 203Ba, which is the side surface of the endpoint detection window 203B, while maintaining a predetermined interval in the axial direction. In other words, in the direction orthogonal to the polishing surface 3A, the bulging parts 203Bb as projection parts are formed at two locations on the outer peripheral part of the endpoint detection window 203B. The thickness (axial dimension) and the outward bulging length of each bulging part 203Bb are the same. The length (height) of the bulging part is preferably 0.1 to 0.5 mm. By setting the length of the bulging part to 0.1 to 0.5 mm, it is possible to ensure the strength of the bulging part and obtain the effect of preventing the endpoint detection window from being detached. Further, the distance (pitch) between the upper and lower bulging parts 203Bb is substantially the same dimension as the thickness thereof. The pitch of the bulging part 203Bb is preferably 0.2 to 0.5 mm. By setting the pitch of the bulging part 203Bb to 0.2 to 0.5 mm, a mixed solution obtained by mixing the urethane prepolymer, which is the material of the polishing layer 3C, and the curing agent with each other easily spreads, a plurality of bulging parts 203Bb is easily formed (processed), and the strength of the bulging part 203Bb can be ensured. Further, the bulging part 203Bb on the upper side is positioned on the lower side from an upper surface 203Bc which is the same as the polishing surface 3A by a dimension shorter than the thickness of the bulging part 203Bb, and the bulging part 203Bb on the lower side is positioned on the upper side of the lower surface 203Bd by approximately half the thickness of the bulging part 203Bb. When the bulging part 203Bb forms a screw thread (spiral), the bulging part 203B is continuously positioned from the upper surface 203Bc to the lower surface 203Bd.

On the other hand, the through-hole 3Ca of the polishing layer 3C is formed so as to be engaged with the original outer peripheral surface 203Ba and the bulging part 203Bb of the endpoint detection window 203B without a gap.

In other words, the original outer peripheral surface 203Ba and the bulging part 203Bb of the endpoint detection window 203B are fitted to the original inner peripheral surface of the through-hole 3Ca without a gap.

As described above, the endpoint detection window 203B of another example has the bulging parts 203Bb for preventing detachment, which are formed at two locations on the outer peripheral part thereof, while recess parts 3Cb engaged with the bulging parts 203Bb without a gap are formed at two locations in the through-hole 3Ca of the polishing layer 3C.

The depth of the plurality of grooves 3Cd formed on the polishing surface 3A is set to be deeper than the upper bulging part 203Bb of the endpoint detection window 203B and to be shallower than the lower bulging part 203Bb. The groove 3Cd holds or discharges the slurry. The polishing layer 3C and the endpoint detection window 203B in the polishing pad 203 of another example are configured as described above.

Next, the method for manufacturing the polishing layer 3C of the polishing pad 203 of another example configured as described above will be described with reference to FIG. 5. The description of the steps common to the present example will be omitted.

First, on the outer peripheral part of the columnar material 200 molded by pouring a mixture obtained by mixing a urethane prepolymer, which is a material for a columnar material, and a curing agent with each other in the first mixing step into the cylindrical mold 99 and curing the mixture in the first molding step, the plurality of flange-shaped bulging parts 200A is formed at equal pitches in the axial direction (projections and recesses forming step, refer to (a) of FIG. 5 and (b) of FIG. 5). In another example, by cutting the outer peripheral part of the columnar material 200, the bulging parts 200A having a predetermined width (up-down dimension) and depth (radial dimension) are formed at a plurality of locations in the axial direction. In other words, in this step, the bulging parts 200A as a plurality of projection parts are formed on the outer peripheral part of the columnar material 200, and accordingly, a plurality of projections and recesses is formed along the axial direction of the outer peripheral part of the columnar material 200. Subsequent steps are common to the present example. In this manner, the polishing layer 3C of the polishing pad 203 is formed, and the location of the columnar material 200 in the polishing layer 3C becomes the endpoint detection window 203B.

In another example, the polishing layer 3C of the polishing pad 203 is produced as described above, and the support layer 3D is adhered to the polishing layer 3C with an adhesive to produce the polishing pad 3. The polishing layer 3C of the polishing pad 203 of another example is attached in a state where the endpoint detection window 203B is engaged with the through-hole 3Ca of the polishing layer 3C without a gap without using an adhesive.

Therefore, during the polishing process in which the polishing surface 3A of the polishing layer 3C slides on the surface being polished 2A of the article being polished 2, the adhesive does not mix into the polishing surface 3A, and adverse effect (scratches and the like) of the article being polished 3A due to the adhesive can be prevented.

Further, in another example, at least bulging parts 203Bb at two locations in the endpoint detection window 203B are engaged with the recess part 3Cb of the through-hole 3Ca of the polishing layer 3C without a gap. In other words, a plurality of projections and recesses formed on the outer peripheral part of the endpoint detection window 203B is in a state of being engaged with the projections and recesses on the inner peripheral surface of the through-hole 3Ca of the polishing layer 3C without a gap.

Therefore, it is possible to prevent the endpoint detection window 203B from detaching from the through-hole 3Ca of the polishing layer 3C during the polishing of the article being polished 2.

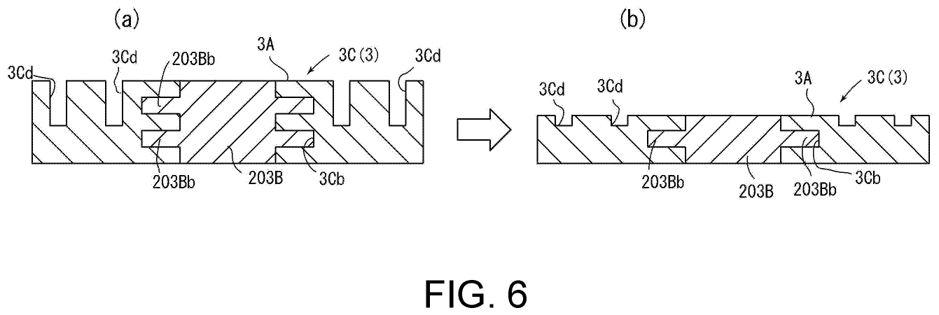

Furthermore, as illustrated in (a) of FIG. 6 and (b) of FIG. 6, as the polishing process for the article being polished 2 is repeated, the polishing surface 3A of the polishing layer 3C in the polishing pad 203 is in a state of being worn away from the initial state shown in (a) of FIG. 6 to the limit of replacement shown in (b) of FIG. 6.

When the polishing surface 3A is worn away, the depth of the groove 3Cd becomes relatively shallow, and when the depth of the groove 3Cd becomes shallow to a predetermined limit, it is time to replace the polishing layer 3C (state of (b) of FIG. 6). Even in this state, the bulging part 203Bb at one location on the lower side remains without being worn away and is engaged with the groove 3Cb.

In other words, at least one bulging part 203Bb remains in the endpoint detection window 203B even at the time when the polishing layer 3C should be replaced. Therefore, according to another example, it is possible to reliably prevent the endpoint detection window 203B from detaching from the through-hole 3Ca of the polishing layer 3C during the polishing of the article being polished 2.

Further, in the projections and recesses forming step illustrated in (b) of FIG. 5, the plurality of bulging parts 200A is formed on the outer peripheral surface of the columnar material 200 by cutting, and accordingly, a plurality of projections and recesses is formed on the outer peripheral surface. However, instead of cutting, a bulging part may be formed in the columnar material by forming projections and recesses in advance in the mold prepared in the first molding step, pouring the material of the columnar material into the mold, and curing the material. Even with the polishing pad 203 having the polishing layer 3C manufactured in this manner, the same actions and effects as those in the above example can be obtained.

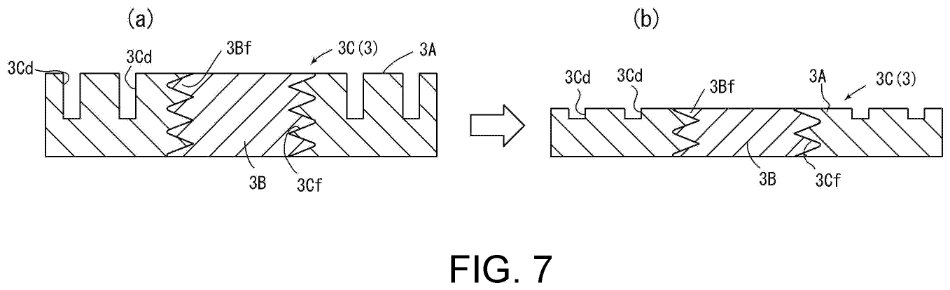

Next, (a) of FIG. 7 illustrates another example regarding the polishing layer 3C of the polishing pad 3. In this example, a male screw 3Bf is formed on the outer peripheral surface of the endpoint detection window 3B, and in accordance with this, on the inner peripheral surface of the through-hole 3Ca of the polishing layer 3C, a female screw 3Cf engaged with the male screw 3Bf without a gap is formed. The manufacturing method of the polishing layer 3C of this example is the same as the manufacturing method of the example illustrated in FIG. 4.

There are threads as projection parts of the male screw 3Bf in the axial direction (up-down direction) at three or more locations, and at least one thread remains even in a state where the groove 3Cd is shallow to the limit of replacement. Other configurations are the same as those of the example illustrated in FIG. 3.

In this example as well, even when the polishing surface 3A of the polishing layer 3C is in a state of being worn away from the initial state illustrated in (a) of FIG. 7 to the limit of replacement illustrated in (b) of FIG. 7, a plurality of threads as projection parts of the male screw 3Bf remains.

Therefore, even with the polishing pad 3 provided with the polishing layer 3C of the example illustrated in (a) of FIG. 7, the same actions and effects as those of each of the above examples can be obtained.

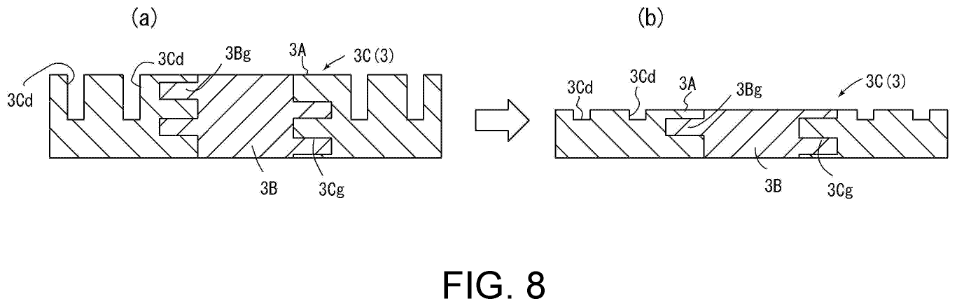

Next, (a) of FIG. 8 illustrates still another example regarding the polishing layer 3C of the polishing pad 3. In this example, a square screw-shaped spiral projection 3Bg is formed on the outer peripheral surface of the endpoint detection window 3B, and in accordance with this, a spiral recess part 3Cg is formed on the inner peripheral surface of the through-hole 3Ca of the polishing layer 3C, and these are in a state of being engaged with each other without a gap.

The projection parts formed by the spiral projections 3Bg are formed at two or more locations in the vertical cross section in the axial direction (up-down direction).

Further, at least one projection part formed by the spiral projection 3Bg is formed on the lower side of the bottom part of the groove 3Cd. Other configurations are the same as those of the example illustrated in FIG. 3. The manufacturing method of the polishing layer 3C of this example is the same as the manufacturing method of the example illustrated in FIG. 4.

In this example as well, even when the polishing surface 3A of the polishing layer 3C is in a state of being worn away from the initial state illustrated in (a) of FIG. 8 to the limit of replacement illustrated in (b) of FIG. 8, a plurality of projection parts of the spiral projections 3Bg remains.

Therefore, even with the polishing pad 3 provided with the polishing layer 3C of the example illustrated in (a) of FIG. 8, the same actions and effects as those of each of the above examples can be obtained.

### REFERENCE SIGNS LIST

1 Polishing device

2 Article being polished

3 Polishing pad

3A Polishing surface

3B Endpoint detection window

3Ba Outer peripheral surface

3C Polishing layer

3Ca Through-hole

What is claimed is:

1. A polishing pad including a polishing layer having a polishing surface for polishing an article being polished and an endpoint detection window provided in a through-hole of the polishing layer to transmit inspection light and reflected light from the article being polished, wherein
a plurality of projection parts is formed on a side part of the endpoint detection window in a direction orthogonal to the polishing surface,
a plurality of recess parts engaged with the projection parts of the endpoint detection window is formed on an inner peripheral surface of the through-hole of the polishing layer, and
the projection parts and the recess parts at a plurality of locations are engaged with each other.

2. The polishing pad according to claim 1, wherein
a groove for holding and/or discharging a slurry is formed on the polishing surface of the polishing layer, and at least one projection part and one recess part are provided in a state of being engaged below a height of a bottom part of the groove.

3. The polishing pad according to claim 2, wherein
the projection part is formed of a bulging part formed on the side part of the endpoint detection window, and the recess part is formed of a recess part formed on the inner peripheral surface of the through-hole of the polishing layer.

4. The polishing pad according to claim 2, wherein
the projection part is a male screw and the recess part is a female screw.

5. The polishing pad according to claim 2, wherein
the projection part has a pitch of 0.2 to 0.5 mm.

6. The polishing pad according to claim 2, wherein
the projection part has a height of 0.15 to 0.5 mm.

7. A method for manufacturing a polishing pad including a polishing layer having a polishing surface for polishing an article being polished and an endpoint detection window provided on the polishing layer to transmit inspection light and reflected light from the article being polished, the method comprising:
a first mixing step of mixing a curing agent and a prepolymer which form the endpoint detection window and forming a mixture of the prepolymer and the curing agent;
a first molding step of producing a material that forms the endpoint detection window by pouring the mixture into a first mold and solidifying the mixture;
a projections and recesses forming step of forming a plurality of projections and recesses on a side surface of the material;
a second mixing step of forming a mixture obtained by mixing the curing agent and the polymer which form the polishing layer;
a second molding step of housing the material, in which the plurality of projections and recesses is formed on the side surface, on an inside of a second mold, and then pouring the mixture formed in the second mixing step into the second mold and solidifying the mixture to produce a molded article in a state where the material is embedded; and
a cutting step of removing the molded article from the second mold and then cutting the molded article to a required thickness to form the polishing layer having the endpoint detection window.

8. The method for manufacturing a polishing pad according to claim 7, wherein
in the projections and recesses forming step, a surface roughness of the side surface of the material after the projections and recesses forming step is adjusted to 2 to 50 μm.

9. The method for manufacturing a polishing pad according to claim 7, wherein
in the projections and recesses forming step, a rough surface is formed on the side surface of the material by using shot blasting or sandpaper, and the plurality of projections and recesses is formed due to the rough surface.

10. The method for manufacturing a polishing pad according to claim 7, wherein
in the projections and recesses forming step, a plurality of bulging parts is formed on the side surface of the material by cutting.

11. The method for manufacturing a polishing pad according to claim 7, wherein
the projections and recesses are formed on a side surface of the first mold used in the first molding step.
